(19) United States
(12) Patent Application Publication
(10) Pub. No.: US 2009/0101949 A1
(43) Pub. Date: Apr. 23, 2009

(54) IMAGE SENSOR AND METHOD FOR MANUFACTURING THE SAME

(76) Inventors: In-Cheol Back, Suwon-si (KR); Han-Choon Lee, Songpa-gu (KR)

Correspondence Address: SHERR & VAUGHN, PLLC, 620 HERNDON PARKWAY, SUITE 200, HERNDON, VA, 20170, US

(21) Appl. No.: 12/249,936

(22) Filed: Oct. 12, 2008

(30) Foreign Application Priority Data
Oct. 22, 2007 (KR) 10-2007-0105865

(51) Int. Cl. H01L 27/146; H01L 31/18

(52) U.S. Cl. 257/292; 438/59; 257/E27.133

(57) ABSTRACT

An image sensor having maximized photosensitivity includes a photodiode and a transistor formed over the semiconductor substrate. A first passivation layer is formed over the semiconductor substrate including the transistor and the photodiode, a pre-metal dielectric layer formed over the first passivation layer and insulating layers having metal wirings formed over the pre-metal dielectric layer. A trench is formed in the insulating layers and the pre-metal dielectric layer exposing a portion of the first passivation layer formed over the photodiode while a second passivation layer formed on sidewalls and a bottom of the trench and over the uppermost surface of the insulating layer such that the second passivation layer directly contacts the portion of the first passivation layer formed over the photodiode. A photosensitive material is then formed over the second passivation layer and buried in the trench.

The present application claims priority under 35 U.S.C. §119 to Korean Patent Application No. P2007-0105865 (filed on Oct. 22, 2007), which is hereby incorporated by reference in its entirety.

### BACKGROUND

An image sensor is a semiconductor device that converts optical images into electrical signals. An image sensor may be classified into a charge coupled device (CCD) image sensor and a complementary metal oxide silicon (CMOS) image sensor (CIS). In a CMOS image sensor, a unit pixel contains a photo-diode and a MOS transistor. Accordingly, the CMOS image sensor sequentially detects electrical signals of each unit pixel in a switching manner, realizing imaging. In the fabrication of such a CMOS image sensor, technical developments have focused on obtaining enhanced photosensitivity.

### SUMMARY

Embodiments relate to an image sensor and a method for manufacturing the same that achieves maximized photosensitivity via improvements in optical characteristics thereof.

Embodiments relate to an image sensor that may include at least one of the following: a semiconductor substrate containing a photodiode; a transistor formed on and/or over the semiconductor substrate; a first passivation layer formed on and/or over the semiconductor substrate including the transistor; a premetal dielectric layer and a metal wiring layer sequentially formed on and/or over the first passivation layer; a trench formed through the metal wiring layer and the premetal dielectric layer over a region where the photodiode is formed; a second passivation layer formed on and/or over sidewalls and a bottom wall of the trench and on and/or over the metal wiring layer; and a photosensitive material formed on and/or over the second passivation layer over the metal wiring layer while being buried in the trench formed with the second passivation layer throughout the sidewalls and the bottom wall of the trench.

Embodiments relate to an image sensor that may include at least one of the following: a semiconductor substrate; a photodiode formed in the semiconductor substrate; a transistor formed over the semiconductor substrate; a first passivation layer formed over the semiconductor substrate including the transistor and the photodiode; a pre-metal dielectric layer formed over the first passivation layer; an insulating layer formed over the pre-metal dielectric layer, the insulating layer having metal wirings formed therein; a trench formed through the insulating layer and the pre-metal dielectric layer and over the photodiode; a second passivation layer formed on sidewalls and a bottom wall of the trench and over the insulating layer; and a photosensitive material formed over the second passivation layer and buried in the trench.

Embodiments relate to an image sensor that may include at least one of the following: a semiconductor substrate; device isolation layers formed in the semiconductor substrate; a photodiode including a first ion implantation layer and a second ion implantation layer formed in the semiconductor substrate; a transistor including a gate pattern formed over the semiconductor substrate, spacers formed on sidewalls of the gate pattern and a third ion implantation region formed in the semiconductor substrate between the gate pattern and one of the device isolation layers; a first nitride layer formed over the semiconductor substrate including the transistor, the photodiode and the device isolation layers; a pre-metal dielectric layer formed over the first nitride layer; a multi-layered insulating layer formed over the pre-metal dielectric layer; metal wirings formed in the insulating layer electrically connected to the transistor; a trench formed in the insulating layer and the pre-metal dielectric layer exposing a portion of the first nitride layer formed over the photodiode; a second nitride layer formed on sidewalls and a bottom of the trench and over the uppermost surface of the insulating layer such that the second nitride layer directly contacts the portion of the first nitride layer formed over the photodiode; and a photosensitive material formed over the second nitride layer and buried in the trench.

Embodiments relate to a method for manufacturing an image sensor that may include at least one of the following: forming a photodiode in a semiconductor substrate; and then forming a transistor on and/or over the semiconductor substrate containing the photodiode; and then sequentially forming a first passivation layer, a premetal dielectric layer and a metal wiring layer on and/or over the entire surface of the semiconductor substrate including the transistor; and then forming a trench through the metal wiring layer and premetal dielectric layer to expose the first passivation layer; and then forming a second passivation layer on and/or over sidewalls and a bottom wall of the trench and on and/or over the metal wiring layer; and then forming a photosensitive material on and/or over the second passivation layer to bury the trench.

Embodiments relate to a method for manufacturing an image sensor that may include at least one of the following: forming a photodiode in a semiconductor substrate; and then forming a transistor over the semiconductor substrate including the photodiode; and then sequentially forming a first passivation layer, a premetal dielectric layer and an insulating layer having metal wirings over the entire surface of the semiconductor substrate including the transistor and the photodiode; and then forming a trench through the insulating layer and the premetal dielectric layer to expose a portion of the first passivation layer formed over the photodiode; and then forming a second passivation layer on sidewalls and a bottom of the trench and over the uppermost surface of the insulating layer such that the second passivation layer directly contacts the portion of the first passivation layer formed over the photodiode and then forming a photosensitive material over the second passivation layer and buried in the trench.

### DRAWINGS

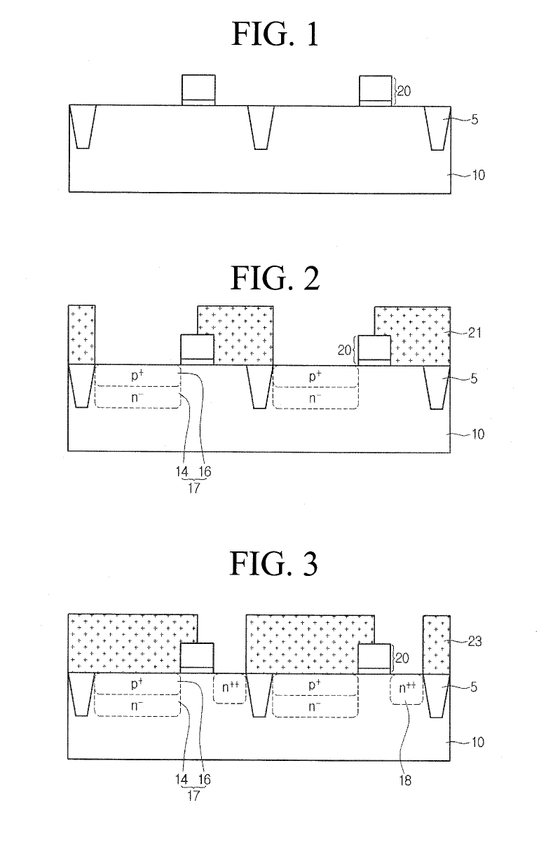

Example FIGS. 1 to 10 illustrate an image sensor and a method for manufacturing an image sensor in accordance with embodiments.

### DESCRIPTION

Reference will now be made in detail to an image sensor and a method for manufacturing the same in accordance with embodiments, examples of which are illustrated in the accompanying example drawing figures. Wherever possible, the same reference numbers will be used throughout the example drawing figures to refer to the same or like parts.

Although the following description refers to the accompanying example drawing figures illustrating a configuration of a CMOS Image Sensor (CIS), embodiments are not limited to a CMOS image sensor, and is applicable to all image sensors including a CCD image sensor, etc.

As illustrated in example FIG. 1, device isolation layer 5 is formed in semiconductor substrate 10 to define active regions. Device isolation layer 5 may be prepared by forming a trench in semiconductor substrate 10 and burying at least one dielectric material in the trench. Gate patterns 20 may then be formed on and/or over semiconductor substrate 10 by forming a gate oxide layer and a gate electrode layer on and/or over semiconductor substrate 10 and thereafter, simultaneously patterning the gate oxide layer and the gate electrode layer. The gate electrode may be made of polysilicon or silicide. Semiconductor substrate 10 may be a high-density p++ type silicon substrate. A low-density p-type epi-layer may be formed in semiconductor substrate 10. The low-density p-type epi-layer in semiconductor substrate 10 can cause a larger and deeper depletion region of photodiodes, which in turn, can maximize the optical-charge collection abilities of photodiodes. The high-density p++ type silicon substrate 10 containing the p-type epi-layer can allow recombination of charges before the charges are diffused into the neighboring unit pixels. This can reduce random diffusion of optical charges and thus, reduce variation in the transmission function of optical charges.

As illustrated in example FIG. 2, photodiodes 17 which include first ion implantation layer 14 and second ion implantation layer 16 may then be formed in semiconductor substrate 10 adjacent to a respective gate pattern 20. Photodiodes 17 may be formed by forming first photoresist pattern 21 on and/or over semiconductor substrate 10, device isolation layer 5 and partially over gate pattern 20 and then sequentially performing first and second ion-implantation processes using first photoresist pattern 21 as a mask. The first ion-implantation process is performed via implantation of n-type dopant ions, thereby forming first ion implantation layer 14. The second ion-implantation process is performed via implantation of p-type dopant ions, thereby forming second ion implantation layer 16 on and/or over first ion implantation layer 14. Second ion implantation layer 16 may be formed such that an uppermost surface thereof is coplanar with the uppermost surface of device isolation layer 5.

As illustrated in example FIG. 3, after removing first photoresist pattern 21, third ion implantation layer 18 is formed in semiconductor substrate 10 between gate pattern 20 and device isolation layer 5. Third ion implantation layer 18 may be formed by forming second photoresist pattern 23 on and/or over semiconductor substrate 10, device isolation layer 5 and photodiode 17 to expose a portion of the uppermost surface of semiconductor substrate 10, and then performing a third ion implantation process using second photoresist pattern 23 as a mask. The third ion implantation process may be performed via implantation of high-density n-type dopant ions. Optical charges produced from photodiodes 17 are transmitted into third ion implantation layer 18, and in turn, are transmitted from the third ion implantation layer 18 to electrical circuits.

As illustrated in example FIG. 4, after removing second photoresist pattern 23, spacer 28 is formed at sidewalls of gate pattern 20 and may overlap photodiode 17 and third ion implantation layer 18. Spacer 28 may be formed by sequentially laminating a first oxide layer, a nitride layer and a second oxide layer on and/or over semiconductor substrate 10 formed with gate pattern 20 to thereby form an oxide-nitride-oxide (ONO) layer on and/or over the entire surface of semiconductor substrate 10 including gate pattern 20. An etching process is then performed on the ONO layer to thereby form spacer 28. In accordance with embodiments, although spacer 28 is described as having an ONO layer configuration, spacer 28 is not limited thereto, and may have an oxide-nitride (ON) layer configuration.

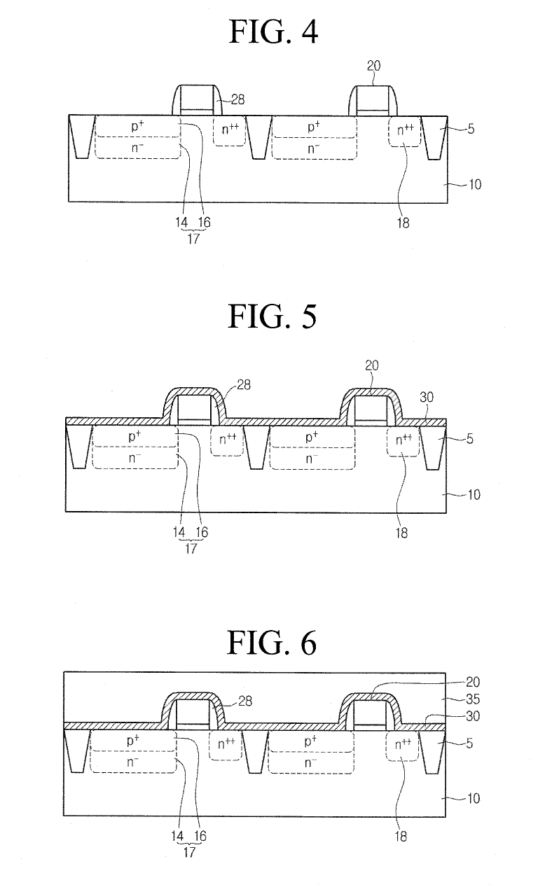

As illustrated in example FIG. 5, first passivation layer 30 is then formed on and/or over semiconductor substrate 10 including device isolation layer 5, gate pattern 20, spacer 28, photodiode 17 and third ion implantation region 18. First passivation layer 30 may be made of SiN at a thickness in a range between approximately 300 Å to 1,000 Å. First passivation layer 30 serves to protect photodiodes 17 and other devices such as transistors, which are formed in semiconductor substrate 10, from the following processes.

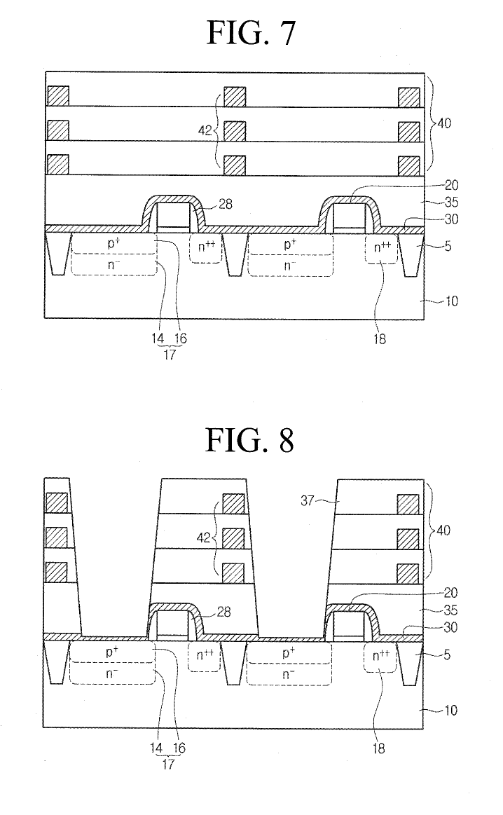

As illustrated in example FIG. 6, pre-metal dielectric (PMD) layer 35 is then formed on and/or over first passivation layer 30. As illustrated in example in FIG. 7, insulating layers 40 containing wirings 42 are formed on and/or over PMD layer 35. Insulating layers 40 have a multilayered structure. Wirings 42 are electrically connected to circuits including transistors formed on and/or over semiconductor substrate 10. As illustrated in example FIG. 8, trenches 37 are then formed through insulating layers 40 and PMD layer 35 exposing a portion of first passivation layer 30 formed on and/or over photodiodes 17. Trenches 37 are formed by forming a third photoresist pattern on and/or over the uppermost insulating layers 40 and then performing an etching process using the third photoresist pattern as a mask. Accordingly, trenches 37 are formed at locations spatially corresponding to photodiodes 17 by etching insulating layers 40 and PMD layer 35. Although first passivation layer 30 may be partially etched upon the etching process for forming trenches 37, first passivation layer 30 is formed uniformly on and/or over photodiodes 17, and thus, protects photodiodes 17 from the etching process. Accordingly, in accordance with embodiments it is possible to prevent damage to photodiodes by the etching process for forming trenches 37.

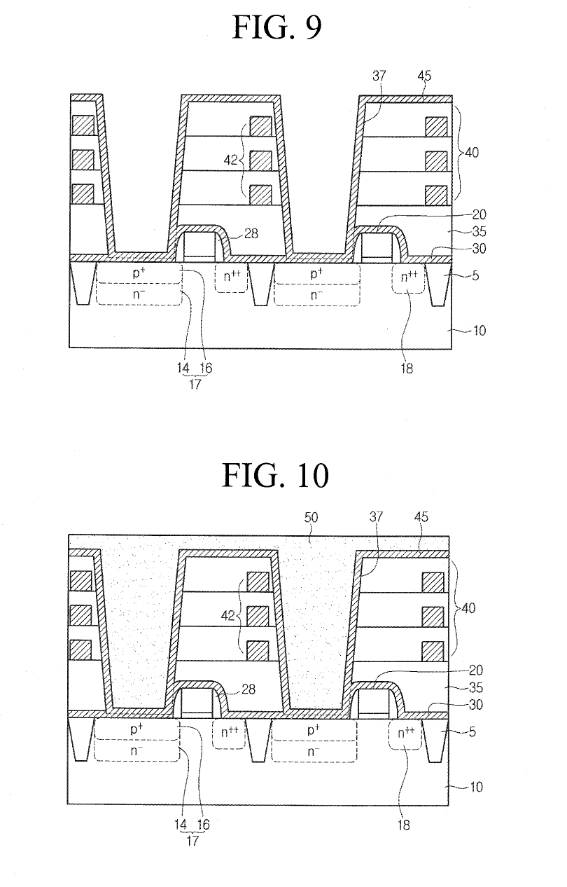

As illustrated in example FIG. 9, second passivation layer 45 is then formed on and/or over the entire surface of semiconductor substrate 10 including insulating layers 40 and in trenches 37 and contacting first passivation layer 30. Second protective layer 45 may be made of SiN at a thickness in a range between approximately 300 Å to 700 Å. Both first passivation layer 30 and second passivation layer 45 is formed uniformly at the bottom of trenches 37 that are formed at locations spatially corresponding to the photodiodes 17. Thereby, second passivation layer 45 is formed on and/or over first passivation layer 30 that is exposed at the bottom of trenches 37. With this configuration, second passivation layer 45 can prevent incident light from entering insulating layers 40. When light is directed toward metal wirings 42, second passivation layer 45 formed at sidewall of trenches 37 prevents the light from entering insulating layers 40. This can prevent a crosstalk phenomenon and consequently, can prevent the occurrence of noise in the image sensor.

As illustrated in example FIG. 10, photosensitive material 50 is then formed on and/or over the entire semiconductor substrate 10 including second passivation layer 45 and insulating layers 40 and buried in trenches 37. Photosensitive material 50 may be made of highly transparent oxides, polymers, photoresist, or the like. A color filter array and micro lenses may then be formed on and/or over photosensitive material 50 to complete construction of the image sensor having semiconductor substrate 10 containing photodiodes 17 transistors provided thereon and/or thereover.

In accordance with embodiments, semiconductor substrate 10 is defined as being divided into a photodiode region containing photodiodes 17 and a transistor region containing transistors. In particular, unit cells of the image sensor are defined by device isolation layer 5 that is formed in semiconductor substrate 10, and each cell defined by device isolation layer 5 is divided into a photodiode region and a transistor region. Here, the transistors include gate pattern 20 and spacer 28 formed at sidewalls of gate pattern 20. The transistors may further include third ion implantation layer 18 formed in semiconductor substrate 10 adjacent to gate pattern 20 and serving to transmit optical charges to circuits. First passivation layer 30 is formed on and/or over semiconductor substrate 10 including the transistors. PMD layer 35 and insulating layers 40, through which trenches 37 are formed, are provided on and/or over first passivation layer 30 over the photodiode region. Insulating layers 40 are formed in multiple layers, each layer containing metal wirings 42. More particularly, after sequentially forming PMD layer 35 and insulating layers 40 on and/or over first passivation layer 30, a portion of PMD layer 35 and insulating layers 40 corresponding to the photodiode region is etched to form trenches 37.

Trenches 37 penetrate through the metal wiring layers 40 and PMD layer 35, and have a depth sufficient to expose first passivation layer 30 of the photodiode region. Trenches 37 are formed at locations corresponding to photodiodes 17 formed in semiconductor substrate 10. Second passivation layer 45 is formed on and/or over sidewalls and a bottom wall of trenches 37 and on and/or over insulating layers 40. Second passivation layer 45 is uniformly formed on and/or over the bottom wall of trenches 37 to a depth sufficient to expose first passivation layer 30 on and/or over the photodiode regions. Accordingly, first passivation layer 30 and second passivation layer 45 can be formed to come into contact with each other at partial portions thereof corresponding to photodiodes 17. Photosensitive material 50 is formed on and/or over second passivation layer 45 and buried in trenches 37.

In the above-described image sensor in accordance with embodiments, when incident light is guided by photosensitive material 50 buried in trenches 37, second passivation layer 45 prevents a portion of the light from entering insulating layers 40. Meanwhile, electric circuits including the above-described transistors may be formed on and/or over semiconductor substrate 10 and wirings 42 of insulating layers 40 are connected to the circuits. Accordingly, such an image sensor can have maximized photosensitivity. Use of a first passivation layer prevents unwanted etching of photodiodes upon an etching process for formation of the trenches, thereby preventing damage to the photodiodes. Furthermore, trenches formed through a premetal dielectric layer allow light to enter the photodiodes through a photosensitive material and the first passivation layer, and a second passivation layer is provided to prevent loss of the incident light. As a result, embodiments can eliminate a problem of light loss due to refraction and reflection and the like by inter-layer dielectrics.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate;
a photodiode formed in the semiconductor substrate;
a transistor formed over the semiconductor substrate;
a first passivation layer formed over the semiconductor substrate including the transistor and the photodiode;
a pre-metal dielectric layer formed over the first passivation layer;
an insulating layer formed over the pre-metal dielectric layer, the insulating layer having metal wirings formed therein;
a trench formed through the insulating layer and the pre-metal dielectric layer and over the photodiode;
a second passivation layer formed on sidewalls and a bottom wall of the trench and over the insulating layer; and
a photosensitive material formed over the second passivation layer and buried in the trench.

2. The image sensor of claim 1, wherein the trench is formed to expose a portion of the first passivation layer formed over the photodiode.

3. The image sensor of claim 1, wherein the first passivation layer and the second passivation layer comprises SiN.

4. The image sensor of claim 3, wherein the first passivation layer is formed at a thickness in a range between approximately 300 Å to 1,000 Å and the second passivation layer is formed at a thickness in a range between approximately 300 Å to 700 Å.

5. The image sensor of claim 1, wherein the photosensitive material comprises any one of an oxide, a polymer and a photoresist.

6. The image sensor of claim 1, wherein the first passivation layer and the second passivation layer directly contact each other at the bottom of the trench.

7. An image sensor comprising:
a semiconductor substrate;
device isolation layers formed in the semiconductor substrate;
a photodiode including a first ion implantation layer and a second ion implantation layer formed in the semiconductor substrate;
a transistor including a gate pattern formed over the semiconductor substrate, spacers formed on sidewalls of the gate pattern and a third ion implantation region formed in the semiconductor substrate between the gate pattern and one of the device isolation layers;
a first nitride layer formed over the semiconductor substrate including the transistor, the photodiode and the device isolation layers;
a pre-metal dielectric layer formed over the first nitride layer;
a multi-layered insulating layer formed over the pre-metal dielectric layer;
metal wirings formed in the insulating layer electrically connected to the transistor;
a trench formed in the insulating layer and the pre-metal dielectric layer exposing a portion of the first nitride layer formed over the photodiode;
a second nitride layer formed on sidewalls and a bottom of the trench and over the uppermost surface of the insulating layer such that the second nitride layer directly contacts the portion of the first nitride layer formed over the photodiode; and
a photosensitive material formed over the second nitride layer and buried in the trench.

8. The image sensor of claim 7, wherein the first nitride layer and the second nitride layer comprises SiN.

9. The image sensor of claim 8, wherein the first nitride layer is formed at a thickness in a range between approximately 300 Å to 1,000 Å and the second nitride layer is formed at a thickness in a range between approximately 300 Å to 700 Å.

10. The image sensor of claim 8, wherein the photosensitive material comprises any one of an oxide, a polymer and a photoresist.

11. The image sensor of claim 8, wherein the second ion implantation layer is formed over the first ion implantation layer.

12. The image sensor of claim 8, wherein the second ion implantation layer is formed such that an uppermost surface thereof is coplanar with the uppermost surface of the device isolation layer and the third ion implantation layer.

13. A method for manufacturing an image sensor comprising:
forming a photodiode in a semiconductor substrate; and then
forming a transistor over the semiconductor substrate including the photodiode; and then
sequentially forming a first passivation layer, a premetal dielectric layer and an insulating layer having metal wirings over the entire surface of the semiconductor substrate including the transistor and the photodiode; and then
forming a trench through the insulating layer and the premetal dielectric layer to expose a portion of the first passivation layer formed over the photodiode; and then
forming a second passivation layer on sidewalls and a bottom of the trench and over the uppermost surface of the insulating layer such that the second passivation layer directly contacts the portion of the first passivation layer formed over the photodiode and then
forming a photosensitive material over the second passivation layer and buried in the trench.

14. The method of claim 13, wherein forming the photodiode comprises sequentially forming a first ion implantation layer in the semiconductor substrate and a second ion implantation layer in the semiconductor substrate over the first ion implantation layer.

15. The method of claim 14, wherein forming the transistor comprises:
forming a gate pattern over the semiconductor substrate; and then
forming spacers on sidewalls of the gate pattern; and then
forming a third ion implantation region in the semiconductor substrate adjacent to the gate pattern and spaced from the photodiode.

16. The method of claim 15, wherein the third ion implantation layer is formed such that an uppermost surface thereof is coplanar with the uppermost surface of the second ion implantation layer.

17. The method of claim 13, wherein the first passivation layer and the second passivation layer comprises a nitride material.

18. The method of claim 17, wherein the nitride material comprises SiN.

19. The method of claim 13, wherein the first passivation layer is formed at a thickness in a range between approximately 300 Å to 1,000 Å and the second passivation layer is formed at a thickness in a range between approximately 300 Å to 700 Å.

20. The method of claim 13, wherein the photosensitive material comprises any one of an oxide, a polymer and a photoresist.
